(19) United States
(12) Patent Application Publication
(10) Pub. No.: US 2006/0107996 A1
(43) Pub. Date: May 25, 2006

(54) Photovoltaic cell

(76) Inventors: Sean Shaheen, Denver, CO (US); Christoph Brabec, Linz (AT); Thomas Fromherz, Rottenegg (AT); Franz Padinger, St. Marien (AT); Serdar Sariciftci, Linz (AT); Erhard Gloetzl, Linz (AT)

Correspondence Address: WILLIAM COLLARD;COLLARD & ROE, P.C., 1077 NORTHERN BOULEVARD, ROSLYN, NY, 11576, US

(21) Appl. No.: 10/258,713

(22) PCT Filed: Apr. 27, 2001
(86) PCT No.: PCT/AT01/00130

§ 371 Date: May 16, 2005

(30) Foreign Application Priority Data
Apr. 27, 2000 (AT) 733/2000

(51) Int. Cl. H01L 31/00

(52) U.S. Cl. 136/263

(57) ABSTRACT

A photovoltaic cell is described having a photoactive layer (4) made of two components, namely a conjugated polymer component as an electron donor and a fullerene component as an electron acceptor. In order to provide advantageous conditions, it is suggested that the two components and their mixed phases have an average largest grain size smaller than 500 nm in at least some sections of photoactive layer (4).

The present invention relates to a photovoltaic cell having a photoactive layer made of two components, namely a conjugated polymer component as an electron donor and a fullerene component as an electron acceptor.

Plastics having extensive π-electron systems, in which single and double bonds follow one another alternately in sequence, are referred to as conjugated plastics. These conjugated plastics have energy bands which are comparable with semiconductors in regard to electron energy, so that they may also be transferred from the non-conductive state into the metallically conductive state through doping. Examples of such conjugated plastics are polyphenylenes, polyvinylphenylenes (PPV), polythiophenes, or polyanilines. The efficiency of energy conversion of photovoltaic polymer cells made of a conjugated polymer is, however, typically between 10⁻³ and 10⁻²%. To improve this efficiency, heterogeneous layers made of two conjugated polymer components have already been suggested (U.S. Pat. No. 5,670,791 A), one polymer component being used as an electron donor and the other polymer component as an electron acceptor. By using fullerenes, particularly buckminsterfullerenes C₆₀, as electron acceptors (U.S. Pat. No. 5,454,880 A), the charge carrier recombination otherwise typical in the photoactive layer may be largely avoided, which leads to an efficiency of 0.6% to 1% under AM (air mass) 1.5 conditions. In spite of this, the achievable efficiency generally remains too low for a cost-effective, technical use of such photoactive layers for constructing photovoltaic cells.

The present invention is therefore based on the object of designing a photovoltaic cell of the type initially described in such a way that a further increase of the efficiency of energy conversion is possible.

The present invention achieves the object described in that both components and their mixed phases have an average largest grain size smaller than 500 nm in at least some sections of the photoactive layer.

The present invention is based on the knowledge that effective charge separation may only be ensured in the contact region between the electron donor and the electron acceptor, so that after photoexcitation of the conjugated polymer components, the excitation energy is only relayed to the fullerene components in the form of electrons in the contact regions with the fullerene components. If the average largest grain size of the components and mixed phases in the photoactive layer is kept smaller than 500 nm, then, due to the enlargement of the surface connected therewith, the proportion of contact between the two components may be increased accordingly, which leads to a significant improvement of the charge separation. The efficiency, which is a function of this charge separation, rose to a characteristic 2.5% under simulated AM 1.5 conditions.

To manufacture photovoltaic cells having a photoactive layer whose average grain size is smaller than 500 nm, a mixture made of the two components and a solvent may be applied as a film to a carrier layer provided with an electron layer, before this film, which forms the photoactive layer, is covered with a counter electrode, as is typical. However, it must be ensured that an appropriate dispersion agent is used as a solvent for both components, in order to ensure the desired fine grain of the photoactive layer. Chlorobenzene may particularly advantageously be used as a dispersion agent in this case.

The effect of the fine-grained structure of the photoactive layer of a photovoltaic cell according to the present invention will be described more detail with reference to the drawing.

FIG. 1 shows the basic construction of a photovoltaic cell according to the present invention in section,

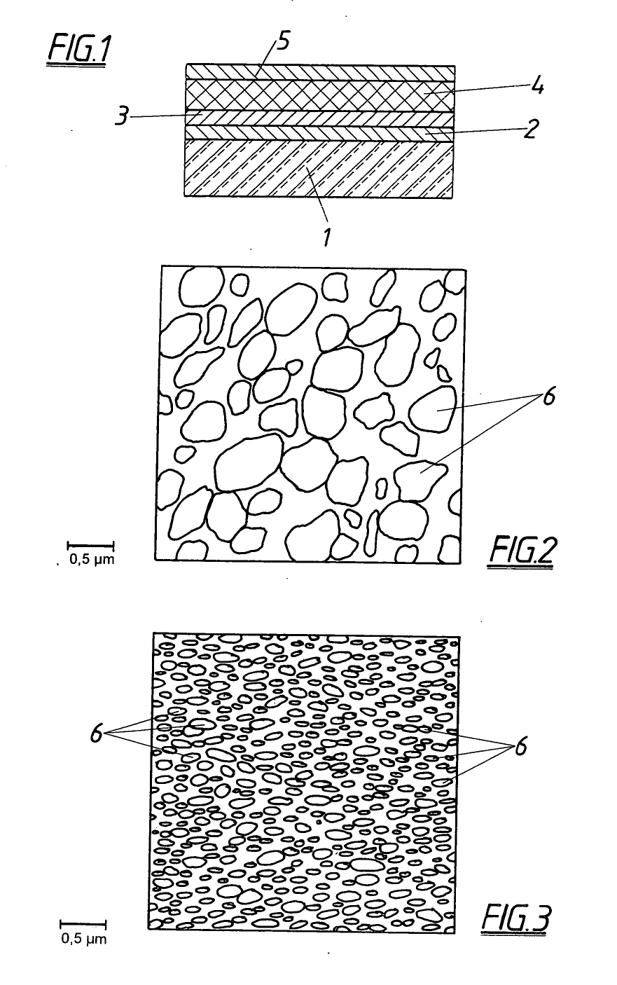

FIG. 2 shows the surface structure of a typical photoactive layer,

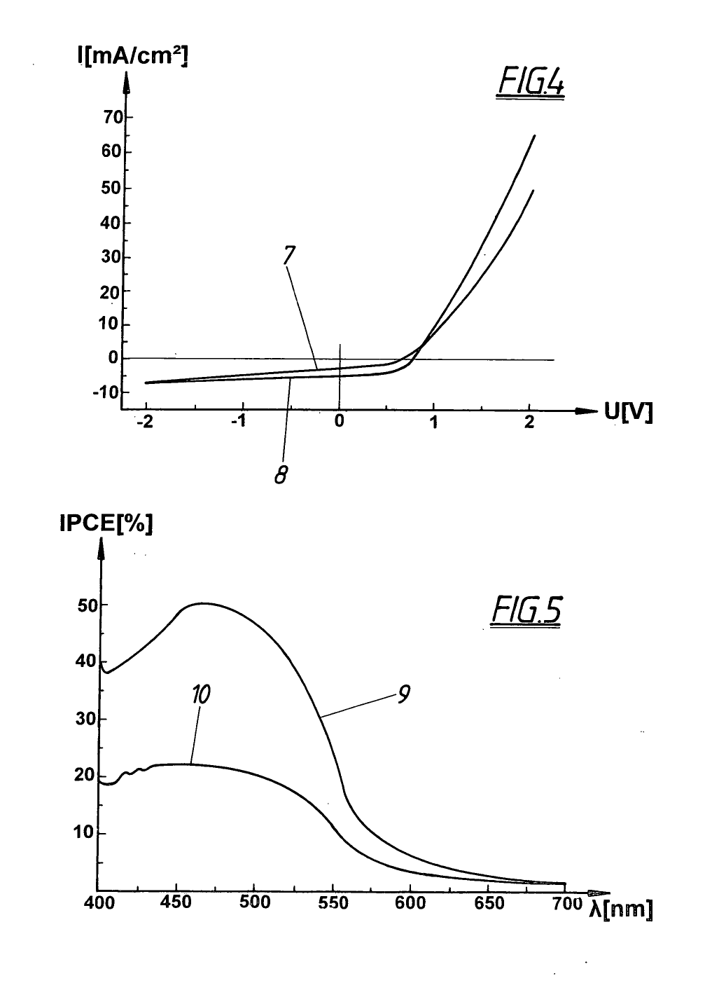

FIG. 3 shows the surface structure of a photoactive layer according to the present invention,

FIG. 4 shows the current-voltage characteristic of a typical photovoltaic cell and a photovoltaic cell according to the present invention, and

FIG. 5 shows the charge yield per incident luminous intensity in relation to the wavelength of the photoexcitation, for a typical photovoltaic cell and for a photovoltaic cell according to the present invention.

As shown in FIG. 1, the photovoltaic cell comprises a transparent glass carrier 1, onto which an electrode layer 2 made of indium/tin oxide (ITO) is applied. This electrode layer 2 generally has a comparatively rough surface structure, so that it is covered with a smoothing layer 3 made of a polymer, typically PEDOT, which is made electrically conductive through doping. Photoactive layer 4, which is made of two components, each having a layer thickness of, for example, 100 nm to a few μm depending on the application method, is applied onto this smoothing layer 3 before counterelectrode 5 is applied. If ITO is used as a hole-collecting electrode, aluminum, which is vapor deposited onto photoactive layer 4, is used as an electron-collecting electrode.

The photoactive layer is made of a conjugated polymer, preferably a PPV derivate, as an electron donor and a fullerene, particularly functionalized fullerene PCBM, as an electron acceptor. The concept of polymer is to be understood to mean both high polymers and oligomers. These two components are mixed with a solvent and applied as a solution onto smoothing layer 3 by, for example, spin coating or dripping. Toluene is used as a typical solvent, however, it cannot ensure the desired fine structure of photoactive layer 4, as is shown in FIG. 2, in which the typical surface structure of such a photoactive layer using toluene as a solvent is illustrated. The grain structure of fullerene components 6 and/or a mixed phase may particularly be seen in atomic force microscopy (tapping-mode AFM images), as is schematically reproduced in FIGS. 2 and 3, while the polymer components and/or a further mixed phase essentially fill up the intervals between the distinct grains. As is shown by the length unit illustrated, a maximum grain size significantly greater than 500 nm results.

However, if a dispersion agent, preferably chlorobenzene, is used as a solvent according to the present invention, then a significantly finer structure is obtained for active layer 4, with an otherwise corresponding composition, which accordingly results in a smoother surface structure, as shown in FIG. 3. The average grain size of less than 500 nm of photoactive layer 4 achievable with the aid of the dispersion agent produces a significant increase of the number of contact points between the electron donor and the electron acceptor and therefore a significantly improved charge separation and reduced charge recombination, which may be read directly from the voltage-current characteristic. In FIG. 4, current density I of the photovoltaic cells to be compared is graphed over voltage U, at an excitation energy of 80 mW/cm² under simulated AM 1.5 conditions. If one compares characteristic 7 of the photovoltaic cell having the coarse-grained structure of photoactive layer 4 to characteristic 8, which was recorded for a photovoltaic cell having a fine-grained structure of photoactive layer 4, one immediately recognizes the improved ratios in a photovoltaic cell according to the present invention as shown in characteristic 8. The short-circuit current measured at voltage 0 V was 2.79 mA/cm² for the known cell, and was 5.24 mA/cm² for the cell according to the present invention. Since the no-load voltage also increased from 710 mV to 770 mV, an increase in efficiency from approximately 1% to 2.6% could be achieved, it being taken into consideration that the bulk factor increased from 0.40 to 0.52 due to the finer structure of the photoactive layer according to the present invention.

The effects according to the present invention may be seen particularly clearly in FIG. 5, in which the charge yield per incident luminous intensity IPCE[%]=1240.Iₖ[μA/cm²]/A[nm].Iₗ[W/m²] is graphed over wavelength λ for the photovoltaic cells to be compared. The short-circuit current is to be entered in the formula above with Iₖ, and the luminous intensity with Iₗ. It is shown that, according to characteristic 9 for the cell according to the present invention in comparison to characteristic 10 of the typical cell, approximately double the charge yield per incident luminous intensity results if the fine structure of heterogeneous photoactive layer 4 has an average grain smaller than 500 nm.

1. A photovoltaic cell having a photoactive layer made of two components, namely a conjugated polymer component as an electron donor and a fullerene component as an electron acceptor,
characterized in that the conjugated polymer component comprises a PPV polymer derivative, and the two components and their mixed phases have an average largest grain size smaller than 500 nm in at least some sections of the photoactive layer.

2. A method for producing a photovoltaic cell according to claim 1, comprising applying a mixture made of the two components and a solvent on a carrier layer, which is provided with an electrode layer, to form a film, and disposing a counterelectrode on this film,
characterized in that a dispersion agent, is added as a solvent to the mixture made of the two components.

3. The photovoltaic cell of claim 1, wherein the fullerene component comprises a functionalized fullerene.

4. The photovoltaic cell of claim 3, wherein the functionalized fullerene is PCBM.

5. The photovoltaic cell of claim 1, further comprising a carrier layer.

6. The photovoltaic cell of claim 5, wherein the carrier layer comprises PEDOT.

7. The photovoltaic cell of claim 1, further comprising an electrode and a counterelectrode.

8. The photovoltaic cell of claim 7, wherein the electrode comprises indium tin oxide.

9. The photovoltaic cell of claim 7, wherein the counterelectrode comprises aluminum.

10. A photovoltaic cell, comprising a photoactive layer containing a conjugated polymer component as an electron donor and a functionalized fullerene as an electron acceptor, wherein the conjugated polymer component, the functionalized fullerene, and their mixed phases have an average largest grain size smaller than 500 nm in at least some sections of the photoactive layer.

11. The photovoltaic cell of claim 10, wherein the conjugated polymer component comprises a PPV derivative.

12. The photovoltaic cell of claim 10, wherein the functionalized fullerene is PCBM.

13. The photovoltaic cell of claim 10, further comprising a carrier layer.

14. The photovoltaic cell of claim 14, wherein the carrier layer comprises PEDOT.

15. The photovoltaic cell of claim 10, further comprising an electrode and a counterelectrode.

16. The photovoltaic cell of claim 15, wherein the electrode comprises indium tin oxide.

17. The photovoltaic cell of claim 15, wherein the counterelectrode comprises aluminum.

18. The method of claim 2, wherein the dispersion agent is chlorobenzene.

19. The method of claim 2, wherein the mixture is applied on the carrier layer by spin coating or dripping.
